(19) United States
(12) Patent Application Publication
(10) Pub. No.: US 2024/0096863 A1
(43) Pub. Date: Mar. 21, 2024

(54) METHOD FOR MANUFACTURING LIGHT-EMITTING SUBSTRATE AND LIGHT-EMITTING SUBSTRATE

(71) Applicant: Shenzhen China Star Optoelectronics Semiconductor Display Technology Co., Ltd., Shenzhen, Guangdong (CN)

(72) Inventor: Xue BAI, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/623,628

(22) PCT Filed: Oct. 27, 2021
(86) PCT No.: PCT/CN2021/126800

§ 371 Date: Apr. 6, 2023

(30) Foreign Application Priority Data
Sep. 30, 2021 (CN) 202111161926.5
Sep. 30, 2021 (CN) 2021111619265

(51) Int. Cl. H01L 25/16; H01L 33/00; H01L 33/52; H01L 33/58

(52) U.S. Cl. CPC H01L 25/167; H01L 33/0095; H01L 33/52; H01L 33/58; H01L 2933/0041

(57) ABSTRACT

Embodiments of the present disclosure disclose a method for manufacturing a light-emitting substrate and a light-emitting substrate. The method for manufacturing a light-emitting substrate includes: forming a plurality of light emitting diode (LED) chips on a substrate, wherein a spacer region is deposed between adjacent LED chips; forming a black photoresist layer on the substrate to cover the plurality of LED chips and the plurality of spacer regions; performing first exposure on the black photoresist layer to reduce the black photoresist layer on the LED chips; and performing second exposure on the black photoresist layer to cure the black photoresist layer.

### FIELD OF INVENTION

The present disclosure relates to the field of display technologies, and in particular, to a method for manufacturing a light-emitting substrate and a light-emitting substrate.

### BACKGROUND OF INVENTION

The micro-light emitting diode (micro-LED) technology has become a hot spot of future display technologies. Compared with a conventional liquid crystal display (LCD) or a conventional organic light emitting diode (OLED) display device, the micro-LED technology has advantages, such as quick response, a high color gamut, a high resolution, and low energy consumption. As a combination of the micro-LED and the back panel, the mini-LED has a contrast and high color rendering performance as high as those of the OLED, costs slightly higher than the LCD but only about 60% of the cost of the OLED, and is easier to implement than the micro-LED and the OLED. Therefore, the mini-LED becomes a hot spot for layout by various panel manufacturers.

The micro-LED/mini-LED technology is an LED miniaturization and matrix technology, which means integrating high-density and microsized LED arrays on a chip, to reduce the distance between pixels from millimeters to micrometers, or even nanometers. In detail, numerous microsized LED chips are disposed on an array substrate, and the distance between the LED chips is relatively small. If no barrier layer is established between the LED chips of the micro-LED/mini-LED or the barrier layer is highly transmissive, the Lambertian light emitted by the LED chips cause excitation of the quantum dot color conversion layers of adjacent pixels, resulting in light crosstalk. Therefore, the display color gamut is greatly reduced.

In the prior art, a black barrier layer is often used to block the light crosstalk between the pixels. The black barrier layer is coated using a process of spraying on an entire surface and then removing black glue on the surface. However, a height difference exists between the micro-LED/mini-LED chips and between binding solders. The height difference between the LED chips is about 20 microns. Therefore, surfaces of some LED chips are still covered by a large amount of black glue after grinding, resulting in uneven light-emitting brightnesses of the LED chips, and a large amount of light is absorbed by the black glue barrier layer covering the surfaces of the LED chips. Therefore, the energy efficiency is relatively low, severely affecting the quality of the micro-LED/mini-LED light-emitting substrate.

### SUMMARY OF INVENTION

### Technical Problem

The present disclosure provides a method for manufacturing a light-emitting substrate and a light-emitting substrate. According to the method for manufacturing a light-emitting substrate, black photoresist over the light emitting diode (LED) chips is pre-cured under a mask, to reduce the black photoresist on the surfaces of the LED chips. In this way, the light-emitting brightnesses of the LED chips are improved, and the energy efficiency is enhanced, resolving the uneven light-emitting brightnesses of the LED chips.

### Technical Solution

According to a first aspect, an embodiment of the present disclosure provides a method for manufacturing a light-emitting substrate. The method includes:
forming a plurality of LED chips on a substrate, wherein a spacer region is defined between adjacent LED chips;
forming a black photoresist layer on the substrate, and planarizing the black photoresist layer to cause the black photoresist layer to cover the plurality of LED chips and fill the spacer regions;
providing a mask, wherein the mask includes a plurality of exposure regions and a plurality of light-shielding regions, the plurality of exposure regions are in a one-to-one correspondence with the plurality of LED chips, and the plurality of light-shielding regions are in a one-to-one correspondence with the plurality of spacer regions; and performing first exposure on the black photoresist layer under the mask, to cause inorganics in the black photoresist layer in the exposure regions to diffuse into the black photoresist layer in the light-shielding regions; and
performing second exposure on the black photoresist layer to cure the black photoresist layer.

Optionally, in some embodiments of the present disclosure, the performing second exposure on the black photoresist layer to cure the black photoresist layer further includes: grinding the cured black photoresist layer to remove the black photoresist layer higher than the LED chips.

Optionally, in some embodiments of the present disclosure, the step of forming the black photoresist layer on the substrate to cover the plurality of LED chips and the plurality of spacer regions includes: coating the black photoresist layer on the substrate.

Optionally, in some embodiments of the present disclosure, the step of forming the black photoresist layer on the substrate to cover the plurality of LED chips and the plurality of spacer regions includes: coating the black photoresist layer on a surface of a conversion substrate, covering the substrate with a side of the conversion substrate that is coated with the black photoresist layer, and pre-baking the conversion substrate to cause the black photoresist layer to be attached to the substrate.

Optionally, in some embodiments of the present disclosure, a material of the black photoresist layer includes at least carbon black, a photoinitiator, and a reactive monomer.

An embodiment of the present disclosure provides another method for manufacturing a light-emitting substrate. The method includes:
forming a plurality of LED chips on a substrate, wherein a spacer region us defined between adjacent LED chips;
forming a black photoresist layer on the substrate to cover the plurality of LED chips and the plurality of spacer regions;
performing first exposure on the black photoresist layer to reduce inorganics in the black photoresist layer over the plurality of LED chips; and
performing second exposure on the black photoresist layer to cure the black photoresist layer.

Optionally, in some embodiments of the present disclosure, the step of forming the black photoresist layer on the substrate to cover the plurality of LED chips and the plurality of spacer regions includes: planarizing the black photoresist layer, to cause the black photoresist layer to fill the spacer regions.

Optionally, in some embodiments of the present disclosure, the step of performing first exposure on the black photoresist layer to reduce the inorganics in the black photoresist layer over the plurality of LED chips includes: providing a mask, wherein the mask includes a plurality of exposure regions and a plurality of light-shielding regions, the plurality of exposure regions are in a one-to-one correspondence with the plurality of LED chips, and the plurality of light-shielding regions are in a one-to-one correspondence with the plurality of spacer regions; and performing first exposure on the black photoresist layer under the mask, to cause inorganics in the black photoresist layer in the exposure regions to diffuse into the black photoresist layer in the light-shielding regions.

Optionally, in some embodiments of the present disclosure, the performing second exposure on the black photoresist layer to cure the black photoresist layer further includes: grinding the cured black photoresist layer to remove the black photoresist layer higher than the LED chips.

Optionally, in some embodiments of the present disclosure, the step of forming the black photoresist layer on the substrate to cover the plurality of LED chips and the plurality of spacer regions includes: coating the black photoresist layer on the substrate.

Optionally, in some embodiments of the present disclosure, the step of forming the black photoresist layer on the substrate to cover the plurality of LED chips and the plurality of spacer regions includes: coating the black photoresist layer on a surface of a conversion substrate, covering the substrate with a side of the conversion substrate that is coated with the black photoresist layer, and pre-baking the conversion substrate to cause the black photoresist layer to be attached to the substrate.

Optionally, in some embodiments of the present disclosure, a material of the black photoresist layer includes at least carbon black, a photoinitiator, and a reactive monomer.

According to another aspect, the present disclosure provides a light-emitting substrate. The light-emitting substrate includes: a substrate; a plurality of LED chips, wherein a spacer region is defined between adjacent LED chips; and a black photoresist layer, formed on the substrate.

Optionally, in some embodiments of the present disclosure, the black photoresist layer includes a first light-shielding portion and a second light-shielding portion. The first light-shielding portion is filled in the spacer regions. The second light-shielding portion is formed at a position over the LED chips.

Optionally, in some embodiments of the present disclosure, at least some of the plurality of LED chips have different heights.

Optionally, in some embodiments of the present disclosure, a material of the black photoresist layer includes at least carbon black, a photoinitiator, and a reactive monomer.

### Beneficial Effects

In the prior art, due to a height difference between the mini-LED chips and between binding solders, surfaces of some LED chips are still covered by a large amount of black photoresist after grinding, and a large amount of light is absorbed by the black photoresist covering the surfaces of the LED chips, resulting in uneven light-emitting brightnesses of the LED chips. Compared with the present disclosure provides a method for manufacturing a light-emitting substrate and a light-emitting substrate. The method for manufacturing the light-emitting substrate includes steps of: forming a plurality of light emitting diode (LED) chips on a substrate, wherein a spacer region exists between adjacent LED chips; forming a black photoresist layer on the substrate to cover the plurality of LED chips and the plurality of spacer regions; performing first exposure on the black photoresist layer to reduce inorganics in the black photoresist layer over the plurality of LED chips; and performing second exposure on the black photoresist layer to cure the black photoresist layer. According to the method for manufacturing a light-emitting substrate, the first exposure is performed on the black photoresist layer over the LED chips, to reduce the inorganics in the black photoresist layer over the LED chips. In this way, the light-emitting brightnesses of the LED chips are improved, and the energy efficiency is enhanced, resolving the uneven light-emitting brightnesses of the LED chips.

### BRIEF DESCRIPTION OF DRAWINGS

To describe the technical solutions of the embodiments of the present disclosure more clearly, the following briefly introduces the accompanying drawings required for describing the embodiments. The accompanying drawings in the following description show only some embodiments of the present disclosure, and a person skilled in the art may still derive other drawings from these accompanying drawings without creative efforts.

FIG. 1 is a schematic flowchart of a first method for manufacturing a light-emitting substrate according to an embodiment of the present disclosure.

FIG. 2 is a schematic diagram of step S1 of the method for manufacturing a light-emitting substrate according to an embodiment of the present disclosure.

FIG. 3a is a schematic diagram I of step S2 of the method for manufacturing a light-emitting substrate according to an embodiment of the present disclosure.

FIG. 3b is a schematic diagram II of step S2 of the method for manufacturing a light-emitting substrate according to an embodiment of the present disclosure.

FIG. 4 is a schematic diagram of step S3 of the method for manufacturing a light-emitting substrate according to an embodiment of the present disclosure.

FIG. 5 is a schematic diagram of step S4 of the method for manufacturing a light-emitting substrate according to an embodiment of the present disclosure.

FIG. 6 is a schematic diagram of step S5 of the method for manufacturing a light-emitting substrate according to an embodiment of the present disclosure.

FIG. 7 is a schematic flowchart of a second method for manufacturing a light-emitting substrate according to an embodiment of the present disclosure.

FIG. 8 is a schematic diagram of a structure of a substrate of the method for manufacturing a light-emitting substrate according to an embodiment of the present disclosure.

FIG. 9 is a schematic diagram of a structure of a light-emitting substrate according to an embodiment of the present disclosure.

10. Substrate, 11. LED chip, 12. Spacer region, 13. Black photoresist layer, 20. Pressing member, 21. Pressing plate, 22. Protective film, 30. Mask, 31. Exposure region, 32. Light-shielding region, 40. Carrier plate, 41. Thermal release film, 42. Double-sided film, 43. Positioning mark, 100. Light-emitting substrate.

### DETAILED DESCRIPTION OF PREFERRED EMBODIMENTS

The following clearly and completely describes the technical solutions in the embodiments of the present disclosure with reference to the accompanying drawings in the embodiments of the present disclosure. Apparently, the described embodiments are only some embodiments rather than all the embodiments of the present disclosure. All other embodiments obtained by a person skilled in the art based on the embodiments of the present disclosure without creative efforts shall fall within the protection scope of the present disclosure.

Embodiments of the present disclosure provide a method for manufacturing a light-emitting substrate and a light-emitting substrate. According to the method for manufacturing a light-emitting substrate, exposure is performed on black photoresist over light emitting diode (LED) chips under a mask, to reduce the black photoresist on the surfaces of the LED chips. In this way, the light-emitting brightnesses of the LED chips are improved, and the energy efficiency is enhanced, thereby resolving the uneven light-emitting brightnesses of the LED chips. Detailed descriptions are separately provided below. It should be noted that the order of description in the following embodiments is not intended to limit the preferred order of the embodiments. In addition, in the description of the present disclosure, the term “including” means “including but not limited to”. Terms such as “first”, “second”, and “third” are only used as labels, which are used to distinguish different objects, and are not intended to describe a specific sequence.

Referring to FIG. 1, FIG. 1 is a schematic flowchart of a first method for manufacturing a light-emitting substrate according to an embodiment of the present disclosure. As shown in FIG. 1, the method for manufacturing a light-emitting substrate provided in the present embodiment of the present disclosure includes the following steps:

Step S1: Form a plurality of LED chips 11 on a substrate 10, wherein a spacer region 12 exists between adjacent LED chips 11.

Step S2: Coat a black photoresist layer 13 on the substrate 10, to cover the plurality of LED chips 11 and the plurality of spacer regions 12.

Step S3: Perform first exposure on the black photoresist layer 13 to reduce inorganics in the black photoresist layer 13 over the plurality of LED chips 11.

Step S4: Perform second exposure on the black photoresist layer 13 to cure the black photoresist layer 13.

It needs to be noted that, a sequence and detailed process operations of steps for manufacturing the light-emitting substrate may be adjusted according to actual needs, which are not limited in the present disclosure.

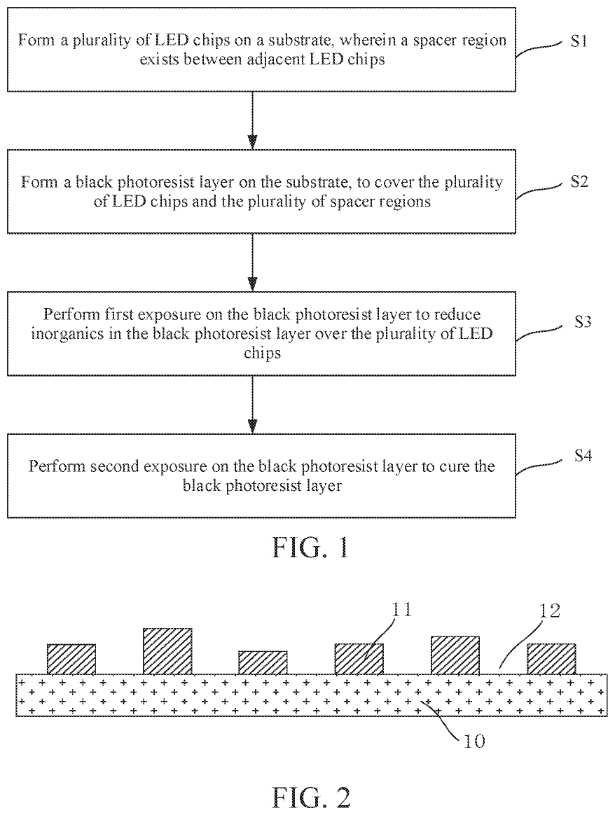

In the present embodiment of the present disclosure, the plurality of LED chips 11 are formed on the substrate 10. The spacer region 12 is formed between the adjacent LED chips 11. Referring to FIG. 2, FIG. 2 is a schematic diagram of step S1 of the method for manufacturing a light-emitting substrate according to an embodiment of the present disclosure.

In the present embodiment of the present disclosure, the substrate 10 is a glass substrate 10. In other implementations, the substrate 10 may be a substrate 10 made of other transparent materials, such as plastic. In the present embodiment, the substrate 10 has a flat surface, so that various layer structures may be laminated on the surface of the substrate 10 to form corresponding devices. The LED chips 11 may be bound on the substrate 10 by means of solder paste printing or solder paste dispensing.

In detail, the method includes: forming an array function layer on the substrate 10; forming a plurality of pads in an array arrangement on the array function layer; and providing a steel mesh (not shown in the figure) for solder paste printing. The steel mesh includes a steel mesh body and a buffer layer. The steel mesh body includes a plurality of first vias in an array arrangement. The plurality of first vias are in a one-to-one correspondence with the plurality of pads. A material of the steel mesh body is not limited to steel, and may be other rigid materials. The steel mesh body is configured to provide positioning for solder paste printing using the first vias therein, so as to realize a solder paste printing process with higher precision.

The buffer layer is attached to a bottom surface of the steel mesh body. An overall outline and a size of the buffer layer is same as those of the steel mesh body. In order to match a shape of the to-be-printed substrate 10, the buffer layer and the steel mesh body are usually in a rectangular shape. Definitely, the to-be-printed substrate may also be in other shapes according to actual process requirements. The buffer layer includes a plurality of second vias in a one-to-one correspondence with the plurality of first vias in an array arrangement.

In the present embodiment of the present disclosure, during solder paste printing using the steel mesh, the buffer layer is aligned to the to-be-printed substrate 10. On one hand, auxiliary positioning is provided by the first vias in the steel mesh. Therefore, compared with direct printing, solder paste printing with higher precision can be realized, and the probability that defects, such as uneven printing, insufficient solder, pseudo soldering, and shifting occur during the printing can be effectively reduced. On the other hand, after the steel mesh presses the substrate 10, the buffer layer can provide buffering, to avoid a yield loss caused by a short circuit or an open circuit of the lines on the substrate 10 when the rigid steel mesh body comes into direct contact with the substrate 10.

In the present embodiment of the present disclosure, a material of the black photoresist layer 13 includes an oligomer containing polymerizable groups, a reactive monomer, a photoinitiator, a black dye, carbon black, graphene, and an additive. By means of the black dye and the carbon black, the black photoresist layer 13 is presented in black.

In the present embodiment of the present disclosure, in order to satisfy a requirement for ultraviolet (UV) curing of the black photoresist layer 13, a mass percent concentration of the carbon black in the black photoresist layer 13 is also required to meet the Beer-Lambert Law: I=I0ekcl. I is a UV radiation intensity at a distance 1 downward from the surface of the black photoresist layer 13, I0 is a UV radiation intensity of the surface of the black photoresist layer 13, k is an extinction coefficient of the carbon black, c is the mass percent concentration of the carbon black in the black photoresist layer 13, and 1 is a range (an irradiation depth/target thickness) where the UV light can reach.

In the present embodiment of the present disclosure, a mass percent of the oligomer containing polymerizable groups is in a range of 60% to 75%, a mass percent of the reactive monomer is in a range of 4% to 15%, a mass percent of the photoinitiator is in a range of 1% to 6%, a mass percent of the black dye is in a range of 1% to 8%, a mass percent of the carbon black is in a range of 0.2% to 1%, a mass percent of the graphene is in a range of 0.1% to 10%, and a mass percent of the additive is in a range of 0% to 2%.

Preferably, the mass percent of the reactive monomer is in a range of 7% to 10%, the mass percent of the photoinitiator is in a range of 2% to 5%, the mass percent of the black dye is in a range of 2% to 2.5%, and the mass percent of the graphene is in a range of 0.1% to 5%.

In the present embodiment of the present disclosure, a particle size of the carbon black is in a range of 50 nm to 100 nm. Since excessive addition of the carbon black causes most UV light to fail to enter the black photoresist layer 13 during the UV curing, affecting the curing efficiency and the curing effect of the black photoresist layer 13, carbon black of a relative low concentration is usually added to the black photoresist layer 13. The relative low concentration is generally in a range of 0.2% to 1%.

In the present embodiment of the present disclosure, a resin system in the black photoresist layer 13 has a large curing reaction speed under the irradiation of the UV light. By means of blackening by adding the carbon black, the black photoresist layer 13 has a relatively high optical density (OD) value. In addition, since the color of the carbon black is fixed, insufficient light shielding caused by the fading of the carbon black over years will not occur. The carbon black is dispersed using a dispersant and fixed using a polymer cross-linked network, sedimentation and uneven dispersing of the carbon black will not occur in the black photoresist layer 13. In addition, by adding the graphene, the flexibility of the black photoresist layer 13 can be increased, achieving desirable resistance to re-machining, and the black photoresist layer 13 has a good desirable conductivity. The black photoresist layer 13 may achieve heat dissipation for a periphery of a panel after being coated on a periphery of a light-emitting substrate. Further, by virtue of the conductivity of the graphene, the static electricity on a surface of the light-emitting substrate can be eliminated. By means of the system formed by the carbon black, the black dye, and the graphene, the black photoresist layer 13 also has desirable resistance to water vapor.

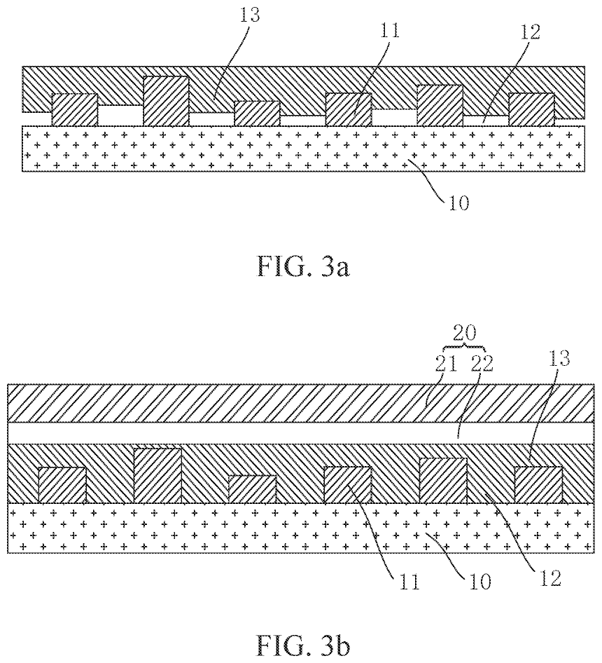

In the present embodiment of the present disclosure, the black photoresist layer 13 is coated on the substrate 10. Referring to FIG. 3, FIG. 3a is a schematic diagram I of step S2 of the method for manufacturing a light-emitting substrate according to an embodiment of the present disclosure.

In detail, the black photoresist layer 13 is coated on the substrate 10 having a matrix array. During the coating of the black photoresist layer 13, the substrate 10 carrying the LED chips 11 may be fixed using a fixture, and film coating may be performed using a coater. The black photoresist layer 13 is uniformly coated on the substrate 10, and is pre-baked. A pre-baking condition may be performing baking for 2 minutes to 5 minutes at 50° C. to 90° C. to evaporate most of solvents in the black photoresist layer 13 coated on the substrate 10.

In the present embodiment of the present disclosure, an operating chamber may also be vacuumized, so that most of the solvents in the black photoresist layer 13 can be quickly evaporated by means of heating in a low-pressure environment, thereby facilitating follow-up exposure and development of the black photoresist layer 13.

In the present embodiment of the present disclosure, the black photoresist layer 13 is planarized, to cause the black photoresist layer 13 to fill the spacer regions 12. Referring to FIG. 3b, FIG. 3b is a schematic diagram II of step S2 of the method for manufacturing a light-emitting substrate according to an embodiment of the present disclosure. In detail, a pressing member 20 is provided. The pressing member 20 includes a pressing plate 21 and a protective film 22. The pressing plate 21 is disposed on the protective film 22. That is to say, the protective film 22 is disposed on a side of the pressing plate 21 that is close to the black photoresist layer 13. The protective film 22 is configured for contact with the black photoresist layer 13. The pressing plate 21 is parallel to the substrate 10. The protective film 22 can keep the cured surface of the black photoresist layer 13 smooth and clean. The pressing plate 21 may be a glass plate and is configured to provide a certain pressure. The pressing plate 21 is pressed to cause the protective film 22 to approach a position over the LED chips 11, to reduce the residual black photoresist layer 13 over the LED chips 11.

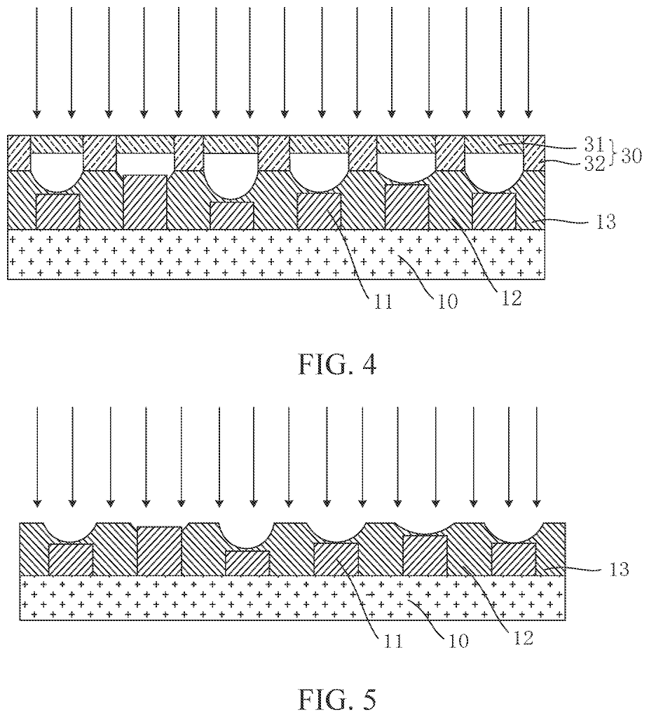

In the present embodiment of the present disclosure, first exposure is performed on the black photoresist layer 13 to reduce inorganics in the black photoresist layer 13 over the plurality of LED chips 11. Referring to FIG. 4, FIG. 4 is a schematic diagram of step S3 of the method for manufacturing a light-emitting substrate according to an embodiment of the present disclosure. In detail, a mask 30 is provided. The mask 30 includes a plurality of exposure regions 31 and a plurality of light-shielding regions 32. The plurality of exposure regions 31 are in a one-to-one correspondence with the plurality of LED chips 11. The plurality of light-shielding regions 32 are in a one-to-one correspondence with the plurality of spacer regions 12. A width difference between the exposure regions 31 and the LED chips 11 is in a range of 0 microns to 5 microns. That is to say, widths of the exposure regions 31 may be at most 5 microns greater than widths of the LED chips 11, or may be at most 5 microns less than the widths of the LED chips 11. In FIG. 4, the widths of the exposure regions 31 are greater than the widths of the LED chips, for example. First exposure is performed on the black photoresist layer 13 under the mask 30, to cause the inorganics in the black photoresist layer 13 in the exposure regions 31 to diffuse into the black photoresist layer 13 in the light-shielding regions 32, thereby reducing the inorganics in the black photoresist layer over the LED chips 11. In this way, the light-emitting brightnesses of the LED chips 11 are increased. It needs to be noted that, the above width is a length of a cross section.

In the present embodiment of the present disclosure, based on the space mass transfer phenomenon between inorganics and organics, when photosensitive inorganics are partially irradiated, a cross-linking reaction occurs between the inorganics and the organics and then a density changes. Therefore, the diffusion coefficient of black inorganics of the irradiated part is different from the diffusion coefficient of the black inorganics of the non-irradiated part, generating a diffusion coefficient difference. Therefore, the inorganic particles flow toward the non-irradiated part from the irradiated part, reducing the black inorganic particles of the irradiated part, thereby improving the light-emitting brightnesses of the LED chips 11.

In the present embodiment of the present disclosure, a condition for the first exposure may be performing UV exposure on the black photoresist layer 13 over the LED chips 11 for 1 minute to 3 minutes under the mask 30.

During the exposure of the black photoresist layer 13 over the LED chips 11, the mask 30 is placed between a light source and the substrate 10 coated with the black photoresist layer 13. UV light emitted by the light source penetrates the mask 30 and then irradiate the substrate 10. When the light irradiating the substrate 10 is relatively strong, the UV light irradiates the black photoresist layer 13 over the LED chips 11, to cause the black photoresist layer 13 over the LED chips 11 to undergo a cross-linking reaction. In detail, the viscosity of the black photoresist layer 13 over the LED chips 11 is increased, so that the black inorganic particles in the black photoresist layer 13 over the LED chips 11 are moved to a dark region of the mask. That is to say, the black inorganic particles in the black photoresist layer 13 over the LED chips 11 are moved to the spacer regions 12 of the LED chips 11. In this way, the black inorganic particle molecules over the LED chips 11 are reduced, the light-emitting brightnesses of the LED chips 11 are improved, and the energy efficiency is enhanced, thereby resolving the uneven light-emitting brightnesses of the LED chips 11.

In the present embodiment of the present disclosure, second exposure is performed on the black photoresist layer 13 to cure the black photoresist layer 13. Referring to FIG. 5, FIG. 5 is a schematic diagram of step S4 of the method for manufacturing a light-emitting substrate according to an embodiment of the present disclosure. A curing condition for performing the second exposure on the black photoresist layer 13 may include curing for 1 minute to 3 minutes at 120° C. to 200° C.

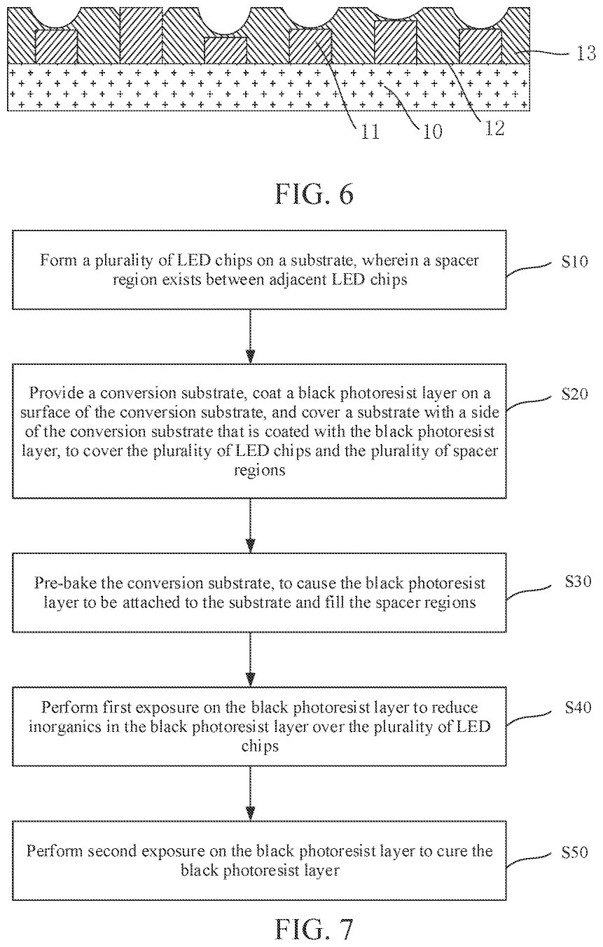

In the present embodiment of the present disclosure, after the second exposure is performed on the black photoresist layer 13, the method further includes step S5 of grinding the cured black photoresist layer 13. Thus, a thickness of the black photoresist layer 13 is not larger than heights of the higher LED chips 11. That is to say, the black photoresist layer 13 higher than the LED chips 11 is removed. Referring to FIG. 6, FIG. 6 is a schematic diagram of step S5 of the method for manufacturing a light-emitting substrate according to an embodiment of the present disclosure. In detail, a grinding process is to perform mould pressing on the black photoresist layer 13. The black photoresist layer 13 is ground using a grinding wheel. A machine is used to control a grinding precision. A part higher than the LED chips 11 is ground to be flush with the higher LED chips 11.

In the prior art, surfaces of some LED chips are still covered by a large amount of black photoresist layers 13 after grinding, and a large amount of light is absorbed by the black photoresist layers 13 covering the surfaces of the LED chips, resulting in uneven light-emitting brightnesses of the LED chips. Compared with the prior art, the present disclosure provides a method for manufacturing a light-emitting substrate. According to the method for manufacturing a light-emitting substrate, exposure is performed on the black photoresist layer 13 over the LED chips 11 is exposed under the mask 30, so that the black inorganic particles in the black photoresist layer 13 on the surfaces of the LED chips 11 are moved toward a dark region of the mask 30. In this way, the light-emitting brightnesses of the LED chips 11 are improved, and the energy efficiency is enhanced, thereby resolving the uneven light-emitting brightnesses of the LED chips 11.

As a detailed implementation of the present disclosure, referring to FIG. 7, FIG. 7 is a schematic flowchart of a second method for manufacturing a light-emitting substrate according to an embodiment of the present disclosure. As shown in FIG. 7, the method for manufacturing a light-emitting substrate provided in the present embodiment of the present disclosure includes the following steps:

Step S10: Form a plurality of LED chips 11 on a substrate 10, wherein a spacer region 12 exists between adjacent LED chips 11.

Step S20: Provide a conversion substrate, coat a black photoresist layer 13 on a surface of the conversion substrate, and cover a substrate 10 with a side of the conversion substrate that is coated with the black photoresist layer 13, to cover the plurality of LED chips 11 and the plurality of spacer regions 12.

Step S30: Pre-bake the conversion substrate, to cause the black photoresist layer 13 to be attached to the substrate 10 and fill the spacer regions 12.

Step S40: Perform first exposure on the black photoresist layer 13 to reduce inorganics in the black photoresist layer 13 over the plurality of LED chips 11.

Step S50: Perform second exposure on the black photoresist layer 13 to cure the black photoresist layer 13.

It needs to be noted that, a sequence and detailed process operations of steps for manufacturing the light-emitting substrate may be adjusted according to actual needs, which are not limited in the present disclosure.

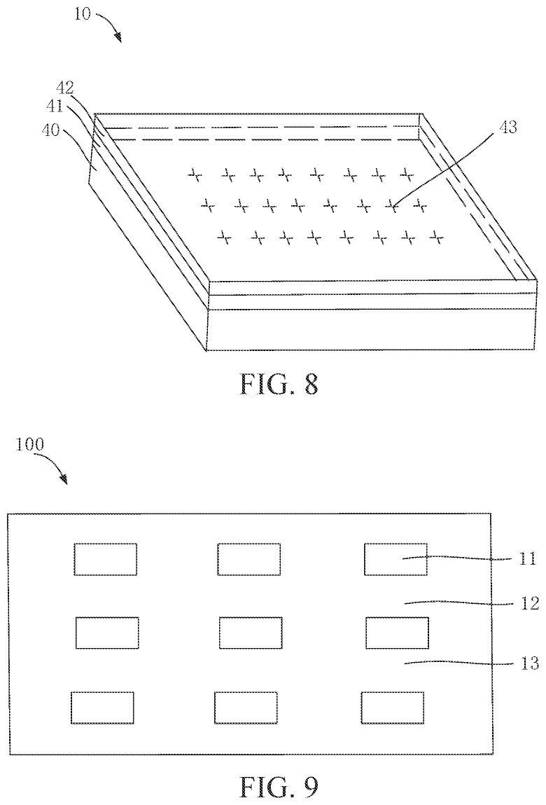

In the present embodiment of the present disclosure, the plurality of LED chips 11 are formed on the substrate 10. The spacer regions 12 are formed between the adjacent LED chips 11. Referring to FIG. 8, FIG. 8 is a schematic diagram of a structure of a substrate of the method for manufacturing a light-emitting substrate according to an embodiment of the present disclosure. The substrate 10 includes a carrier plate 40, a thermal release film 41, and a double-sided film 42. The thermal release film 41 is disposed on the carrier plate 40. The double-sided film 42 is disposed on a side of the thermal release film 41 that is away from the carrier plate 40. The carrier plate 40 is a steel plate. Matrix positioning marks 43 of the LED chips 11 are disposed on the carrier plate 40. The thermal release film 41 is viscous. After being heated, the thermal release film has no viscosity, and therefore is easy to peel off. The double-sided film 42 may be a silica gel double-sided film 42 with viscosity on both sides. The carrier plate 40, the thermal release film 41, and the double-sided film 42 jointly form a carrier for the LED chips 11. The carrier plate 40, the thermal release film 41, and the double-sided film 42 may be attached using a laminator machine having a film pressing roller.

Matrix arrays of the LED chips 11 are arranged on the double-sided film 42. In detail, since the thermal release film 41 and the double-sided film 42 have a certain transparency, the matrix positioning marks 43 on the carrier plate 40 may be determined over the double-sided film 42. For example, a visual inspection instrument may be used for positioning, and then the matrix arrays of the LED chips 11 may be arranged on the double-sided film 42 according to the matrix positioning marks 43 using devices, such as a film arranging machine. A gap region exists between the adjacent LED chips 11.

In the present embodiment of the present disclosure, a conversion substrate (not shown in the figure) is provided. The black photoresist layer 13 is coated on a surface of the conversion substrate. A side of the conversion substrate that is coated with the black photoresist layer 13 covers the substrate 10. The conversion substrate may be a release film. The black photoresist layer 13 is coated on a surface of the release film. The release film coated with the black photoresist layer 13 is turned and attached to the substrate 10 bound with the LED chips 11.

In the present embodiment of the present disclosure, the black photoresist layer 13 is evenly coated on the conversion substrate. A pressing member 20 is pressed on the conversion substrate to cause the black photoresist layer 13 to fill the gap regions. In addition, pre-baking is performed. A pre-baking condition may be performing baking for 2 minutes to 5 minutes at 50° C. to 90° C., to evaporate most of solvents in the black photoresist layer 13 coated on the conversion substrate.

In the present embodiment of the present disclosure, an operating chamber may also be vacuumized, so that most of the solvents in the black photoresist layer 13 can be quickly evaporated by means of heating in a low-pressure environment, thereby facilitating follow-up exposure and development of the black photoresist layer 13. The black photoresist layer 13 is vacuumized by means of pressurization and pre-baked, the black photoresist layer 13 is attached to the substrate 10 and fills the spacer regions 12 of the LED chips 11.

In the present embodiment of the present disclosure, first exposure is performed on the black photoresist layer 13 to reduce inorganics in the black photoresist layer 13 over the plurality of LED chips 11. In detail, a mask 30 is provided. The mask 30 includes a plurality of exposure regions 31 and a plurality of light-shielding regions 32. The plurality of exposure regions 31 are in a one-to-one correspondence with the plurality of LED chips 11. The plurality of light-shielding regions 32 are in a one-to-one correspondence with the plurality of spacer regions 12.

In the present embodiment of the present disclosure, based on the space mass transfer phenomenon between inorganics and organics, when photosensitive inorganics are partially irradiated, a cross-linking reaction occurs between the inorganics and the organics and then a density changes. Therefore, the diffusion coefficient of black inorganics of the irradiated part is different from the diffusion coefficient of the black inorganics of the non-irradiated part, generating a diffusion coefficient difference. Therefore, the inorganic particles flow toward the non-irradiated part from the irradiated part, reducing the black inorganic particles of the irradiated part, thereby improving the light-emitting brightnesses of the LED chips 11.

In the present embodiment of the present disclosure, an exposure condition may be performing UV exposure on the black photoresist layer 13 over the LED chips 11 for 1 minute to 3 minutes under the mask 30. During the exposure of the black photoresist layer 13 over the LED chips 11, the mask 30 is placed between a light source and the substrate 10 coated with the black photoresist layer 13. UV light emitted by the light source penetrates the mask 30 and then irradiate the substrate 10. When the light irradiating the substrate 10 is relatively strong, the UV light irradiates the black photoresist layer 13 over the LED chips 11, to cause the black photoresist layer 13 over the LED chips 11 to undergo a cross-linking reaction. In detail, the viscosity of the black photoresist layer 13 over the LED chips 11 is increased, so that the black inorganic particles in the black photoresist layer 13 over the LED chips 11 are moved to a dark region of the mask. That is to say, the black inorganic particles in the black photoresist layer 13 over the LED chips 11 are moved to the spacer regions 12 of the LED chips 11. In this way, the black inorganic particle molecules over the LED chips 11 are reduced, the light-emitting brightnesses of the LED chips 11 are improved, and the energy efficiency is enhanced, thereby resolving the uneven light-emitting brightnesses of the LED chips 11.

In the present embodiment of the present disclosure, second exposure is performed on the black photoresist layer 13 to cure the black photoresist layer 13. A curing condition for performing exposure on the black photoresist layer 13 may be performing curing for 1 minute to 3 minutes at 120° C. to 200° C.

In the present embodiment of the present disclosure, after the black photoresist layer 13 is formed, the method further includes step S60 of grinding the cured black photoresist layer 13. Thus, a thickness of the black photoresist layer 13 is not larger than heights of the higher LED chips 11. That is to say, the black photoresist layer 13 higher than the LED chips 11 is removed.

Moreover, the present disclosure further provides a light-emitting substrate. Referring to FIG. 9, FIG. 9 is a schematic diagram of a structure of a light-emitting substrate according to an embodiment of the present disclosure. The light-emitting substrate 100 includes: a substrate 10; a plurality of LED chips 11, wherein a spacer region 12 exists between adjacent LED chips 11; and a black photoresist layer 13, formed on the substrate 10.

In the present embodiment of the present disclosure, the black photoresist layer 13 includes a first light-shielding portion (not shown in the figure) and a second light-shielding portion (not shown in the figure). The first light-shielding portion is filled in the spacer regions 12 of the LED chips 11. The second light-shielding portion covers at least some of the LED chips 11 from a direction over the LED chips. It may be learned from FIGS. 4 to 6 that, a height of the first light-shielding portion filled in the spacer regions 12 of the LED chips 11 is greater than or equal to a height of the second light-shielding portion covering at least some of the LED chips 11 from the direction over the LED chips. In detail, the second light-shielding portion covers some lower ones of the LED chips 11 from the direction over the LED chips or covers only a part of some lower ones of the LED chips 11 from the direction over the LED chips. The height of the first light-shielding portion equals the height of the highest LED chip 11 in the plurality of LED chips 11 after the black photoresist layer 13 is planarized. That is to say, the second light-shielding portion over the highest LED chips 11 is removed by means of grinding.

In the present embodiment of the present disclosure, at least some of the plurality of LED chips have different heights.

As a detailed implementation of the present disclosure, before the black photoresist layer 13 is coated on the substrate 10, a thin film transistor (not shown in the figure) is formed on a surface of the substrate 10. The black photoresist layer 13 is formed on the thin film transistor. In detail, the thin film transistor includes a gate electrode, a gate insulating layer, an active layer, a source electrode, and a drain electrode successively laminated.

As a detailed implementation of the present disclosure, after the thin film transistor is formed on the substrate 10, a color resist layer is formed on the thin film transistor. The black photoresist layer 13 is formed on the color resist layer.

In the prior art, due to a height difference between the LED chips and between binding solders, surfaces of some LED chips are still covered by a large amount of black glue after grinding, and a large amount of light is absorbed by the black glue covering the surfaces of the LED chips, resulting in uneven light-emitting brightnesses of the LED chips. Compared with the prior art, the present disclosure provides a light-emitting substrate. According to the light-emitting substrate, exposure is performed on the black photoresist layer 13 over the LED chips 11 under the mask 30 based on the space mass transfer phenomenon between inorganics and organics, so that black inorganic particles on the surfaces of the LED chips 11 are moved to the dark region of the mask. In this way, the black inorganic particle molecules on the surfaces of the LED chips 11 are reduced, the light-emitting brightnesses of the LED chips 11 are improved, and the energy efficiency is enhanced, thereby resolving the uneven light-emitting brightnesses of the LED chips 11. Therefore, the light-emitting substrate has higher display quality.

The light-emitting substrate is applicable to any product having a display function, such as a liquid crystal display device, an electronic paper, a mobile phone, a tablet computer, a television, a display, a notebook computer, a digital photo frame, or a navigator.

The method for manufacturing a light-emitting substrate and a light-emitting substrate provided by the present disclosure are described above in detail. Although the principles and implementations of the present disclosure are described by using specific examples in this specification, the descriptions of the foregoing embodiments are merely intended to help understand the method and the core idea of the present disclosure. Meanwhile, a person skilled in the art may make modifications to the specific implementations and application range according to the idea of the present disclosure. In conclusion, the content of this specification is not construed as a limitation to the present disclosure.

What is claimed is:

1. A method for manufacturing a light-emitting substrate, comprising following steps:
forming a plurality of light emitting diode (LED) chips on a substrate, wherein a spacer region is defined between adjacent LED chips;
forming a black photoresist layer on the substrate, and planarizing the black photoresist layer to cause the black photoresist layer to cover the plurality of LED chips and fill the spacer regions;
providing a mask, wherein the mask comprises a plurality of exposure regions and a plurality of light-shielding regions, the plurality of exposure regions are in a one-to-one correspondence with the plurality of LED chips, and the plurality of light-shielding regions are in a one-to-one correspondence with the plurality of spacer regions; performing first exposure on the black photoresist layer under the mask, to cause inorganics in the black photoresist layer in the exposure regions to diffuse into the black photoresist layer in the light-shielding regions; and
performing second exposure on the black photoresist layer to cure the black photoresist layer.

2. The method for manufacturing a light-emitting substrate as claimed in claim 1, wherein the performing second exposure on the black photoresist layer to cure the black photoresist layer further comprises:
grinding the cured black photoresist layer to remove the black photoresist layer higher than the LED chips.

3. The method for manufacturing a light-emitting substrate as claimed in claim 1, wherein the step of forming the black photoresist layer on the substrate to cover the plurality of LED chips and the plurality of spacer regions comprises:
coating the black photoresist layer on the substrate.

4. The method for manufacturing a light-emitting substrate as claimed in claim 1, wherein the step of forming the black photoresist layer on the substrate to cover the plurality of LED chips and the plurality of spacer regions comprises:
coating the black photoresist layer on a surface of a conversion substrate, covering the substrate with a side of the conversion substrate that is coated with the black photoresist layer, and pre-baking the conversion substrate to cause the black photoresist layer to be attached to the substrate.

5. The method for manufacturing a light-emitting substrate as claimed in claim 1, wherein a material of the black photoresist layer comprises at least carbon black, a photoinitiator, and a reactive monomer.

6. A method for manufacturing a light-emitting substrate, comprising following steps:
forming a plurality of light emitting diode (LED) chips on a substrate, wherein a spacer region is defined between adjacent LED chips;
forming a black photoresist layer on the substrate to cover the plurality of LED chips and the plurality of spacer regions;
performing first exposure on the black photoresist layer to reduce inorganics in the black photoresist layer over the plurality of LED chips; and
performing second exposure on the black photoresist layer to cure the black photoresist layer.

7. The method for manufacturing a light-emitting substrate as claimed in claim 6, wherein the step of forming the black photoresist layer on the substrate to cover the plurality of LED chips and the plurality of spacer regions comprises:
planarizing the black photoresist layer, to cause the black photoresist layer to fill the spacer regions.

8. The method for manufacturing a light-emitting substrate as claimed in claim 6, wherein the step of performing first exposure on the black photoresist layer to reduce the inorganics in the black photoresist layer over the plurality of LED chips comprises:
providing a mask, wherein the mask comprises a plurality of exposure regions and a plurality of light-shielding regions, the plurality of exposure regions are in a one-to-one correspondence with the plurality of LED chips, and the plurality of light-shielding regions are in a one-to-one correspondence with the plurality of spacer regions; and
performing first exposure on the black photoresist layer under the mask, to cause inorganics in the black photoresist layer in the exposure regions to diffuse into the black photoresist layer in the light-shielding regions.

9. The method for manufacturing a light-emitting substrate as claimed in claim 6, wherein the performing second exposure on the black photoresist layer to cure the black photoresist layer further comprises:
grinding the cured black photoresist layer to remove the black photoresist layer higher than the LED chips.

10. The method for manufacturing a light-emitting substrate as claimed in claim 6, wherein the step of forming the black photoresist layer on the substrate to cover the plurality of LED chips and the plurality of spacer regions comprises:
coating the black photoresist layer on the substrate.

11. The method for manufacturing a light-emitting substrate as claimed in claim 6, wherein the step of forming the black photoresist layer on the substrate to cover the plurality of LED chips and the plurality of spacer regions comprises:
coating the black photoresist layer on a surface of a conversion substrate, covering the substrate with a side of the conversion substrate that is coated with the black photoresist layer, and pre-baking the conversion substrate to cause the black photoresist layer to be attached to the substrate.

12. The method for manufacturing a light-emitting substrate as claimed in claim 6, wherein a material of the black photoresist layer comprises at least carbon black, a photoinitiator, and a reactive monomer.

13. A light-emitting substrate, comprising:
a substrate;
a plurality of light emitting diode (LED) chips, wherein a spacer region is defined between adjacent LED chips; and
a black photoresist layer disposed on the substrate.

14. The light-emitting substrate as claimed in claim 13, wherein the black photoresist layer comprises a first light-shielding portion and a second light-shielding portion, the first light-shielding portion is filled in the spacer regions, and the second light-shielding portion is formed at a position over the LED chips.

15. The light-emitting substrate as claimed in claim 13, wherein at least some of the plurality of LED chips have different heights.

16. The light-emitting substrate as claimed in claim 13, wherein a material of the black photoresist layer comprises at least carbon black, a photoinitiator, and a reactive monomer.
